(19) United States
(12) Patent Application Publication
(10) Pub. No.: US 2026/0276743 A1
(43) Pub. Date: Sep. 17, 2026

(54) CONTROL DEVICE, POWER SUPPLY SYSTEM, AND CONTROL METHOD

(71) Applicant: HONDA MOTOR CO., LTD., Tokyo (JP)

(72) Inventor: Kenta Shuto, Wako-shi (JP)

(21) Appl. No.: 19/560,757

(22) Filed: Mar. 9, 2026

(30) Foreign Application Priority Data
Mar. 11, 2025 (JP) 2025-038205

(51) Int. Cl. G01R 31/67; B64C 29/00; B64D 27/34; B64D 27/35; B64D 31/16; B64D 45/00; G01R 31/00

(52) U.S. Cl. CPC G01R 31/67; B64C 29/0016; B64D 27/34; B64D 27/35; B64D 31/16; B64D 45/00; G01R 31/008; B64D 2221/00

(57) ABSTRACT

A control device is equipped with a current value determination unit that determines whether a current value acquired using a current sensor that detects a charging/discharging current of a power storage device is less than or equal to a determination threshold value used for determining whether charging or discharging is occurring, a control unit which, if the current value determination unit has determined that the current value acquired by the current sensor is less than or equal to the determination threshold value, carries out a control in order to make the current value greater than the determination threshold value, and a disconnection determination unit which determines, if, despite the control being carried out by the control unit, the current value acquired using the current sensor is less than or equal to the determination threshold value, that a disconnection has occurred in a wiring connected to the power storage device.

### CROSS-REFERENCE TO RELATED APPLICATIONS

This application is based upon and claims the benefit of priority from Japanese Patent Application No. 2025-038205 filed on Mar. 11, 2025, the contents of which are incorporated herein by reference.

### BACKGROUND OF THE INVENTION

### FIELD OF THE INVENTION

The present disclosure relates to a control device, an electrical power supply system, and a control method.

### DESCRIPTION OF THE RELATED ART

In JP 2022-160916 A, a disconnection detection method for detecting a disconnection in an electrical power supply pathway is disclosed.

### SUMMARY OF THE INVENTION

There is a long awaited need for a technique that is capable of suitably determining whether or not a disconnection has occurred.

The present invention has the object of solving the aforementioned problem.

A first aspect of the present disclosure is characterized by a control device provided in an electrical power supply system configured to be capable of supplying electrical power from an electrical power generating device and an electrical power storage device to a load device, and further, to be capable of supplying electrical power from the electrical power generating device to the electrical power storage device, the control device comprising an electrical current value determination unit configured to determine whether or not an electrical current value acquired using an electrical current sensor configured to detect a charging or discharging electrical current of the electrical power storage device is less than or equal to a determination threshold value used for determining whether or not charging or discharging is occurring, a control unit which, in the case that it is determined by the electrical current value determination unit that the electrical current value acquired by the electrical current sensor is less than or equal to the determination threshold value, is configured to carry out a control in order to make the electrical current value greater than the determination threshold value, and a disconnection determination unit which, in the case that, despite the control being carried out by the control unit in order to make the electrical current value greater than the determination threshold value, the electrical current value acquired using the electrical current sensor is less than or equal to the determination threshold value, is configured to determine that a disconnection has occurred in a wiring connected to the electrical power storage device.

A second aspect of the present disclosure is characterized by a control device provided in an electrical power supply system configured to be capable of supplying electrical power from a first electrical power generating device and a first electrical power storage device to a first winding of a double-winding motor, and to be capable of supplying electrical power from the first electrical power generating device to the first electrical power storage device, and further, to be capable of supplying electrical power from a second electrical power generating device and a second electrical power storage device to a second winding of the double-winding motor, and to be capable of supplying electrical power from the second electrical power generating device to the second electrical power storage device, the control device comprising an electrical current value determination unit configured to determine whether or not an electrical current value acquired using an electrical current sensor configured to detect a charging or discharging electrical current of the first electrical power storage device is less than or equal to a determination threshold value used for determining whether or not charging or discharging is occurring, a control unit which, in the case that it is determined that the electrical current value acquired by the electrical current sensor is less than or equal to the determination threshold value, is configured to carry out a control in order to make the electrical current value greater than the determination threshold value, and a disconnection determination unit which, in the case that, despite the control being carried out by the control unit in order to make the electrical current value greater than the determination threshold value, the electrical current value acquired using the electrical current sensor is less than or equal to the determination threshold value, is configured to determine that a disconnection has occurred in a wiring connected to the first electrical power storage device.

A third aspect of the present disclosure is characterized by an electrical power supply system comprising the control device according to the first aspect.

A fourth aspect of the present disclosure is characterized by a control method for an electrical power supply system configured to be capable of supplying electrical power from an electrical power generating device and an electrical power storage device to a load device, and further, to be capable of supplying electrical power from the electrical power generating device to the electrical power storage device, the control method comprising an electrical current value determination step of determining whether or not an electrical current value acquired using an electrical current sensor configured to detect a charging or discharging electrical current of the electrical power storage device is less than or equal to a determination threshold value used for determining whether or not charging or discharging is occurring, a control step in which, in the case that it is determined in the electrical current value determination step that the electrical current value acquired by the electrical current sensor is less than or equal to the determination threshold value, carries out a control in order to make the electrical current value greater than the determination threshold value, and a disconnection determination step of determining, in the case that, despite the control being carried out in the control step in order to make the electrical current value greater than the determination threshold value, the electrical current value acquired using the electrical current sensor is less than or equal to the determination threshold value, that a disconnection has occurred in a wiring connected to the electrical power storage device.

A fifth aspect of the present disclosure is characterized by a control method for an electrical power supply system configured to be capable of supplying electrical power from a first electrical power generating device and a first electrical power storage device to a first winding of a double-winding motor, and to be capable of supplying electrical power from the first electrical power generating device to the first electrical power storage device, and further, to be capable of supplying electrical power from a second electrical power generating device and a second electrical power storage device to a second winding of the double-winding motor, and to be capable of supplying electrical power from the second electrical power generating device to the second electrical power storage device, the control method comprising an electrical current value determination step of determining whether or not an electrical current value acquired using an electrical current sensor configured to detect a charging or discharging electrical current of the first electrical power storage device is less than or equal to a determination threshold value used for determining whether or not charging or discharging is occurring, a control step which, in the case that it is determined in the electrical current value determination step that the electrical current value acquired by the electrical current sensor is less than or equal to the determination threshold value, carries out a control in order to make the electrical current value greater than the determination threshold value, and a disconnection determination step of determining, in the case that, despite the control being carried out in the control step in order to make the electrical current value greater than the determination threshold value, the electrical current value acquired using the electrical current sensor is less than or equal to the determination threshold value, that a disconnection has occurred in a wiring connected to the first electrical power storage device.

According to the present disclosure, it is possible to suitably determine whether or not a disconnection has occurred.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a schematic diagram of a moving object;

FIG. 2 is a schematic diagram of an electrical power supply system according to one embodiment;

FIG. 3 is a schematic diagram showing an example of a first electrical power generating device in the one embodiment;

FIG. 4 is a schematic diagram showing an example of an electric motor (a double winding motor) according to the one embodiment;

FIG. 5 is a schematic diagram showing an example of a first electrical power storage device in the one embodiment;

FIG. 6 is a control block diagram of a control device in the one embodiment;

FIG. 7 is a diagram showing the operation of the electrical power supply system in the one embodiment;

FIG. 8 is a flowchart of a disconnection inspection process;

FIG. 9 is a table showing an input and output electrical power in the electrical power supply system at a time of normal operation, and an input and output electrical power in the electrical power supply system at a time during the disconnection inspection (at a time of a first control);

FIG. 10 is a table showing an input and output electrical power in the electrical power supply system at a time of normal operation, and an input and output electrical power in the electrical power supply system at a time during the disconnection inspection (at a time of a second control);

FIG. 11 is a table showing an input and output electrical power in the electrical power supply system at a time of normal operation, and an input and output electrical power in the electrical power supply system at a time during the disconnection inspection (at a time of a first control); and

FIG. 12 is a table showing an input and output electrical power in the electrical power supply system at a time of normal operation, and an input and output electrical power in the electrical power supply system at a time during the disconnection inspection (at a time of a second control).

### DETAILED DESCRIPTION OF THE INVENTION

In the case that a disconnection occurs in a wiring to which an electrical current sensor is connected, an electrical current value acquired by the electrical current sensor becomes less than or equal to a determination threshold value (usually zero). In contrast to this feature, even in the case that an electrical current simply is not flowing through the wiring to which the current sensor is connected, the electrical current value acquired by the electrical current sensor becomes less than or equal to the determination threshold value. Therefore, in the case that the electrical current value acquired by the electrical current sensor is less than or equal to the determination threshold value, it is not possible to distinguish between whether the wiring is disconnected or whether an electrical current is simply not flowing therethrough. The present disclosure described below makes it possible to determine, using an electrical current sensor, whether or not a disconnection has occurred in a wiring to which the electrical current sensor is connected.

### 1. Moving Object

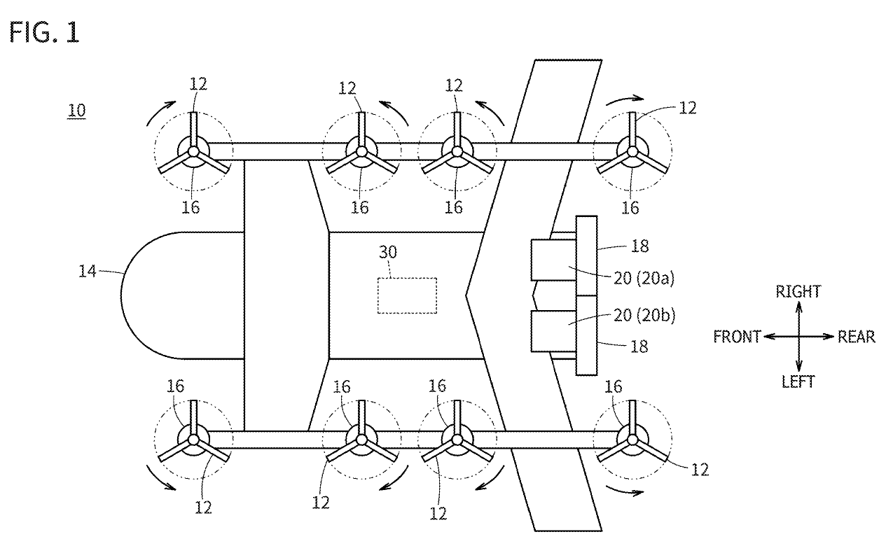

FIG. 1 is a schematic diagram of a moving object 10. The moving object 10 of the one embodiment is an electric vertical takeoff and landing aircraft (eVTOL aircraft). The moving object 10 is equipped with eight VTOL rotors 12. The VTOL rotors 12 generate an upwardly directed thrust with respect to an airframe 14. The moving object 10 is equipped with eight electric motors 16. One of the electric motors 16 drives one of the VTOL rotors 12. The moving object 10 includes two cruise rotors 18. The cruise rotors 18 generate a forwardly directed thrust with respect to the airframe 14. The moving object 10 is equipped with two electric motors 20 (20a, 20b). The electric motors 20 are double winding motors. One of the electric motors 20 drives one of the cruise rotors 18. The moving object 10 is equipped with an electrical power supply system 30, which will be described later. The moving object 10 is not limited to being an aircraft, but may be a ship, an automobile, a train, or the like.

### 2. Configuration of Electrical Power Supply System

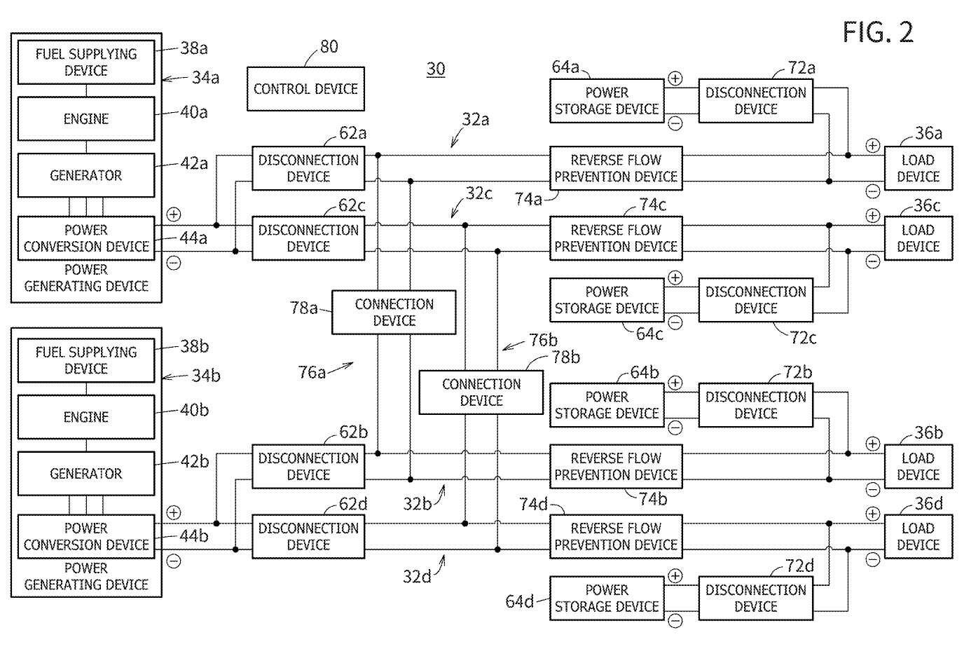

FIG. 2 is a schematic diagram of the electrical power supply system 30 according to the one embodiment. As shown in FIG. 2, the electrical power supply system 30 includes a first electrical power supply circuit 32a, a second electrical power supply circuit 32b, a third electrical power supply circuit 32c, and a fourth electrical power supply circuit 32d. The first electrical power supply circuit 32a supplies a direct current (DC) electrical power output from a first electrical power generating device 34a to a first load device 36a. The second electrical power supply circuit 32b supplies a DC electrical power output from a second electrical power generating device 34b to a second load device 36b. The third electrical power supply circuit 32c supplies a DC electrical power output from the first electrical power generating device 34a to a third load device 36c. The fourth electrical power supply circuit 32d supplies a DC electrical power output from the second electrical power generating device 34b to a fourth load device 36d.

### 2-1. Electrical Power Generating Device

The electrical power supply system 30 comprises the first electrical power generating device 34a and the second electrical power generating device 34b. The first electrical power generating device 34a includes a first fuel supplying device 38a, a first engine 40a, a first electrical power generator 42a, and a first electrical power conversion device 44a. The second electrical power generating device 34b includes a second fuel supplying device 38b, a second engine 40b, a second electrical power generator 42b, and a second electrical power conversion device 44b. The first fuel supplying device 38a and the second fuel supplying device 38b are each equipped with an electronically controlled injector. The first fuel supplying device 38a supplies fuel to the first engine 40a. The second fuel supplying device 38b supplies fuel to the second engine 40b. The first engine 40a and the second engine 40b, for example, are gas turbine engines. Moreover, it should be noted that the first engine 40a and the second engine 40b may be other engines such as reciprocating engines. The first electrical power generator 42a and the second electrical power generator 42b are motor generators that are also capable of functioning as electric motors. The first electrical power conversion device 44a and the second electrical power conversion device 44b are capable of converting an electrical power from a three-phase alternating current (AC) electrical power into a DC electrical power, and converting an electrical power from a DC electrical power into a three-phase AC electrical power.

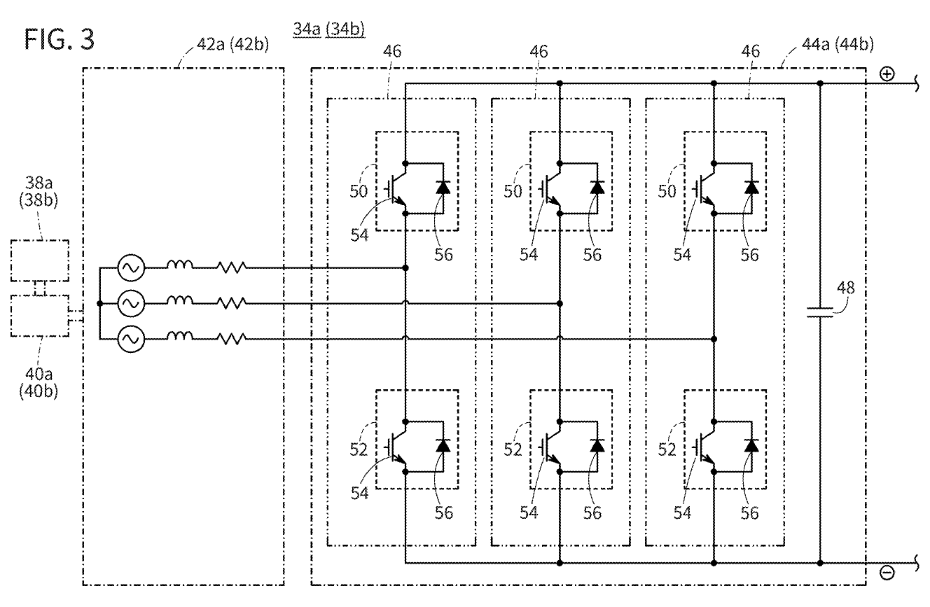

FIG. 3 is a schematic diagram showing an example of the first electrical power generating device 34a in the one embodiment. The configuration of the second electrical power generating device 34b is the same as the configuration of the first electrical power generating device 34a. As shown in FIG. 3, the first electrical power conversion device 44a that is provided in the first electrical power generating device 34a includes three power element units 46 corresponding to each of the three-phase voltages that are output from the first electrical power generator 42a, and a smoothing capacitor 48. The configurations of the three power element units 46 are mutually the same.

The power element units 46 include an upper arm 50 and a lower arm 52. Each of the upper arm 50 and the lower arm 52 includes a switching element 54 and a diode 56. In the power element units 46, the switching element 54 of the upper arm 50 and the switching element 54 of the lower arm 52 are mutually connected in series with each other. A first end part of the switching element 54 of the upper arm 50 is connected to a positive electrode wiring of the first electrical power conversion device 44a. A second end part of the switching element 54 of the upper arm 50 and a first end part of the switching element 54 of the lower arm 52 are connected to one of the three-phase terminals of the first electrical power generator 42a. A second end part of the switching element 54 of the lower arm 52 is connected to a negative electrode wiring of the first electrical power conversion device 44a. An anode of the diode 56 is connected to a second end part of the switching element 54. A cathode of the diode 56 is connected to a first end part of the switching element 54.

Each of the switching elements 54 is a semiconductor switch such as a MOSFET (Metal Oxide Semiconductor Field Effect Transistor), an IGBT (Insulated Gate Bipolar Transistor), or the like.

The first electrical power generator 42a is driven by the first engine 40a and thereby generates a three-phase AC electrical power. The first electrical power conversion device 44a converts the three-phase AC electrical power output from the first electrical power generator 42a into a DC electrical power. By the control of a control device 80, an ON time period of each of the power element units 46 of the first electrical power conversion device 44a is adjusted, and thereby the magnitude of the DC electrical power output from the first electrical power conversion device 44a is adjusted. Similarly, the magnitude of the DC electrical power output from the second electrical power conversion device 44b is adjusted.

The first electrical power conversion device 44a and the second electrical power conversion device 44b may also include various sensors such as voltage sensors and current sensors and the like, and various elements such as fuses, relays, breakers, diodes, transistors, resistors, coils, capacitors, and the like.

### 2-2. Load Devices

As shown in FIG. 2, the electrical power supply system 30 comprises the first load device 36a, the second load device 36b, the third load device 36c, and the fourth load device 36d. Each of the load devices is equipped with a plurality of electrically powered machines. For example, each of the first load device 36a, the second load device 36b, the third load device 36c, and the fourth load device 36d is equipped with two of the electric motors 16. An inverter (not shown) is connected to each of the two electric motors 16. The inverter converts an input DC electrical power into a three-phase AC electrical power. The electric motors 16 are driven by the three-phase AC electrical power.

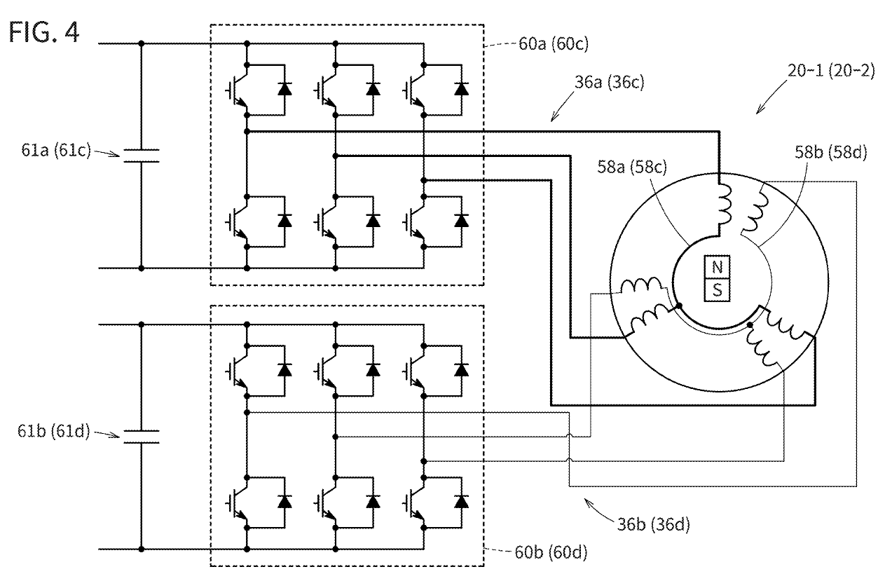

FIG. 4 is a schematic diagram showing an example of an electric motor 20-1 (a double winding motor) according to the one embodiment. As shown in FIG. 4, the configurations of an electric motor 20-2, an inverter 60c, an inverter 60d, a smoothing capacitor 61c, and a smoothing capacitor 61d are the same as the configurations of the electric motor 20-1, an inverter 60a, an inverter 60b, a smoothing capacitor 61a, and a smoothing capacitor 61b.

The first load device 36a comprises a first winding 58a of the electric motor 20-1 which is a double-winding motor. The second load device 36b comprises a second winding 58b of the electric motor 20-1 which is a double-winding motor. The first winding 58a and the second winding 58b are provided together on the stator of the electric motors 20. In this manner, the first load device 36a and the second load device 36b have a common electric motor 20-1. The inverter 60a and the smoothing capacitor 61a are connected to the first winding 58a. The inverter 60a converts an input DC electrical power into a three-phase AC electrical power. The inverter 60b and the smoothing capacitor 61b are connected to the second winding 58b. The inverter 60b converts an input DC electrical power into a three-phase AC electrical power. The electric motor 20-1 is driven by the three-phase AC electrical power that is supplied to the first winding 58a, and the three-phase AC electrical power that is supplied to the second winding 58b.

Similarly, the third load device 36c comprises a first winding 58c of the electric motor 20-2 which is a double-winding motor. The fourth load device 36d comprises a second winding 58d of the electric motor 20-2 which is a double-winding motor.

The first load device 36a, the second load device 36b, the third load device 36c, and the fourth load device 36d may include a non-illustrated DC/DC conversion device and a low voltage drive device. The DC/DC conversion device causes the voltage of the input DC electrical power to be reduced, and the low voltage drive device is driven by the DC electrical power.

The first load device 36a, the second load device 36b, the third load device 36c, and the fourth load device 36d may also include various sensors such as voltage sensors and current sensors and the like, and various elements such as fuses, relays, breakers, diodes, transistors, resistors, coils, capacitors, and the like.

### 2-3. Disconnection Devices

The electrical power supply system 30 is equipped with disconnection devices 62a to 62d. The disconnection device 62a is capable of disconnecting the first electrical power generating device 34a from the first electrical power supply circuit 32a. The disconnection device 62b is capable of disconnecting the second electrical power generating device 34b from the second electrical power supply circuit 32b. The disconnection device 62c is capable of disconnecting the first electrical power generating device 34a from the third electrical power supply circuit 32c. The disconnection device 62d is capable of disconnecting the second electrical power generating device 34b from the fourth electrical power supply circuit 32d.

The disconnection device 62a can be switched, by a non-illustrated contactor, between a state in which the first electrical power generating device 34a is disconnected from the first electrical power supply circuit 32a, and a state in which the first electrical power generating device 34a is connected to the first electrical power supply circuit 32a. Similarly, the disconnection device 62b can be switched, by a non-illustrated contactor, between a state in which the second electrical power generating device 34b is disconnected from the second electrical power supply circuit 32b, and a state in which the second electrical power generating device 34b is connected to the second electrical power supply circuit 32b.

The disconnection device 62c can be switched, by a non-illustrated contactor, between a state in which the first electrical power generating device 34a is disconnected from the third electrical power supply circuit 32c, and a state in which the first electrical power generating device 34a is connected to the third electrical power supply circuit 32c. Similarly, the disconnection device 62d can be switched, by a non-illustrated contactor, between a state in which the second electrical power generating device 34b is disconnected from the fourth electrical power supply circuit 32d, and a state in which the second electrical power generating device 34b is connected to the fourth electrical power supply circuit 32d.

The disconnection devices 62a to 62d may have a relay instead of the contactor. The disconnection devices 62a to 62d may have a breaker instead of the contactor. The disconnection devices 62a to 62d may have a semiconductor switch instead of the contactor.

### 2-4. Electrical Power Storage Devices

The electrical power supply system 30 is equipped with a first electrical power storage device 64a, a second electrical power storage device 64b, a third electrical power storage device 64c, and a fourth electrical power storage device 64d. The first electrical power storage device 64a is connected in parallel with the first electrical power generating device 34a to the first electrical power supply circuit 32a. The second electrical power storage device 64b is connected in parallel with the second electrical power generating device 34b to the second electrical power supply circuit 32b. The third electrical power storage device 64c is connected in parallel with the first electrical power generating device 34a to the third electrical power supply circuit 32c. The fourth electrical power storage device 64d is connected in parallel with the second electrical power generating device 34b to the fourth electrical power supply circuit 32d.

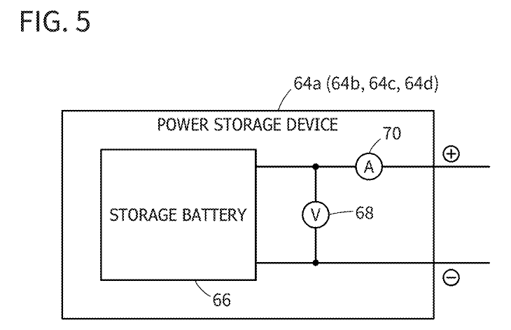

FIG. 5 is a schematic diagram showing an example of the first electrical power storage device 64a in the one embodiment. As shown in FIG. 5, the configurations of the second electrical power storage device 64b, the third electrical power storage device 64c, and the fourth electrical power storage device 64d are the same as the configuration of the first electrical power storage device 64a. The first electrical power storage device 64a includes a storage battery 66. The storage battery 66, for example, may be a lithium ion battery or another type of battery. The first electrical power storage device 64a, the second electrical power storage device 64b, the third electrical power storage device 64c, and the fourth electrical power storage device 64d may each include a large-capacity capacitor instead of the storage battery 66.

The first electrical power storage device 64a includes a voltage sensor 68 and an electrical current sensor 70. The voltage sensor 68 is connected to a positive terminal and a negative terminal of the storage battery 66. The voltage sensor 68 measures a potential difference between the terminals of the storage battery 66. The electrical current sensor 70 is disposed on a positive wiring connected to the positive terminal of the storage battery 66 or on a negative wiring connected to the negative terminal of the storage battery 66. The electrical current sensor 70 measures the electrical current flowing through the positive wiring or the negative wiring.

The first electrical power storage device 64a, the second electrical power storage device 64b, the third electrical power storage device 64c, and the fourth electrical power storage device 64d may also include other various sensors, various elements such as fuses, relays, breakers, diodes, transistors, resistors, coils, capacitors, and the like.

### 2-5. Disconnection Devices

As shown in FIG. 2, the electrical power supply system 30 is equipped with disconnection devices 72a to 72d. The disconnection device 72a is capable of disconnecting the first electrical power storage device 64a from the first electrical power supply circuit 32a and the first load device 36a. The disconnection device 72b is capable of disconnecting the second electrical power storage device 64b from the second electrical power supply circuit 32b and the second load device 36b. The disconnection device 72c is capable of disconnecting the third electrical power storage device 64c from the third electrical power supply circuit 32c and the third load device 36c. The disconnection device 72d is capable of disconnecting the fourth electrical power storage device 64d from the fourth electrical power supply circuit 32d and the fourth load device 36d.

The disconnection device 72a can be switched, by a non-illustrated contactor, between a state in which the first electrical power storage device 64a is disconnected from the first electrical power supply circuit 32a and the first load device 36a, and a state in which the first electrical power storage device 64a is connected to the first electrical power supply circuit 32a and the first load device 36a. Similarly, the disconnection device 72b can be switched, by a non-illustrated contactor, between a state in which the second electrical power storage device 64b is disconnected from the second electrical power supply circuit 32b and the second load device 36b, and a state in which the second electrical power storage device 64b is connected to the second electrical power supply circuit 32b and the second load device 36b.

Further, the disconnection device 72c can be switched, by a non-illustrated contactor, between a state in which the third electrical power storage device 64c is disconnected from the third electrical power supply circuit 32c and the third load device 36c, and a state in which the third electrical power storage device 64c is connected to the third electrical power supply circuit 32c and the third load device 36c. Similarly, the disconnection device 72d can be switched, by a non-illustrated contactor, between a state in which the fourth electrical power storage device 64d is disconnected from the fourth electrical power supply circuit 32d and the fourth load device 36d, and a state in which the fourth electrical power storage device 64d is connected to the fourth electrical power supply circuit 32d and the fourth load device 36d.

The disconnection devices 72a to 72d may have a relay instead of the contactor. The disconnection devices 72a to 72d may have a breaker instead of the contactor. The disconnection devices 72a to 72d may have a semiconductor switch instead of the contactor.

### 2-6. Reverse Flow Prevention Devices

The electrical power supply system 30 is equipped with reverse flow prevention devices 74a to 74d. The reverse flow prevention device 74a limits the supply of the electrical power from the first electrical power storage device 64a to the first electrical power supply circuit 32a and the first electrical power generating device 34a. The reverse flow prevention device 74b limits the supply of the electrical power from the second electrical power storage device 64b to the second electrical power supply circuit 32b and the second electrical power generating device 34b. The reverse flow prevention device 74c limits the supply of the electrical power from the third electrical power storage device 64c to the third electrical power supply circuit 32c and the first electrical power generating device 34a. The reverse flow prevention device 74d limits the supply of the electrical power from the fourth electrical power storage device 64d to the fourth electrical power supply circuit 32d and the second electrical power generating device 34b.

Each of the reverse flow prevention devices 74a to 74d comprises, for example, a diode. Each of the reverse flow prevention devices 74a to 74d may comprise a transistor that bypasses the diode. By an ON signal being supplied to the transistor, for example, the transistor permits the supply of the electrical power from the electrical power storage device to the electrical power generating device.

### 2-7. Connection Devices

The electrical power supply system 30 comprises a first connection circuit 76a. The first connection circuit 76a is equipped with a first connection device 78a. Normally, the first connection device 78a disconnects the first electrical power supply circuit 32a and the second electrical power supply circuit 32b. At a time when an abnormality occurs, the first connection device 78a can connect the first electrical power supply circuit 32a and the second electrical power supply circuit 32b.

The electrical power supply system 30 comprises a second connection circuit 76b. The second connection circuit 76b is equipped with a second connection device 78b. Normally, the second connection device 78b disconnects the third electrical power supply circuit 32c and the fourth electrical power supply circuit 32d. At a time when an abnormality occurs, the second connection device 78b can connect the third electrical power supply circuit 32c and the fourth electrical power supply circuit 32d.

In addition to the configuration described above, the electrical power supply system 30 may include various sensors such as a voltage sensor, a current sensor and the like, and various elements such as a fuse, a resistor, a coil, and a capacitor and the like.

### 2-8. Control Device

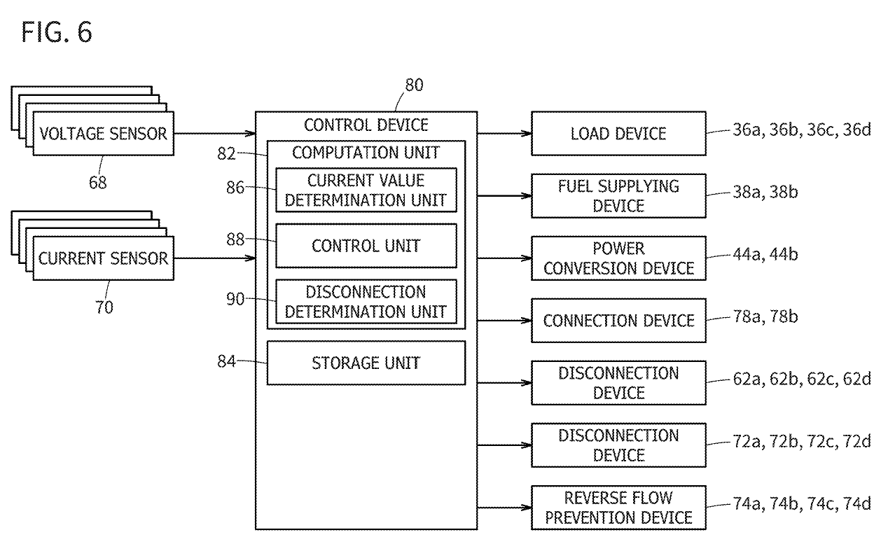

FIG. 6 is a control block diagram of the control device 80 in the one embodiment. The electrical power supply system 30 is equipped with the control device 80. The control device 80 serves to control the first load device 36a, the second load device 36b, the third load device 36c, the fourth load device 36d, the first fuel supplying device 38a, the second fuel supplying device 38b, the first electrical power conversion device 44a, the second electrical power conversion device 44b, the disconnection devices 62a to 62d, the disconnection devices 72a to 72d, the reverse flow prevention devices 74a to 74d, the first connection device 78a, and the second connection device 78b.

The control device 80 includes a computation unit 82 and a storage unit 84. The computation unit 82 is a processor such as a CPU (Central Processing Unit) or a GPU (Graphics Processing Unit) or the like. The computation unit 82 includes an electrical current value determination unit 86, a control unit 88, and a disconnection determination unit 90. The electrical current value determination unit 86, the control unit 88, and the disconnection determination unit 90 can be realized by programs stored in the storage unit 84 being executed by the computation unit 82. At least a portion of the electrical current value determination unit 86, the control unit 88, and the disconnection determination unit 90 may be realized by an integrated circuit such as an ASIC (Application Specific Integrated Circuit) or an FPGA (Field-Programmable Gate Array) or the like. At least a portion of the electrical current value determination unit 86, the control unit 88, and the disconnection determination unit 90 may be realized by an electronic circuit including a discrete device.

The storage unit 84 is a computer readable non-transitory tangible storage medium. The storage unit 84 is constituted by a non-illustrated volatile memory and a non-illustrated nonvolatile memory. The volatile memory, for example, is a RAM (Random Access Memory) or the like. The nonvolatile memory, for example, is a ROM (Read Only Memory), a flash memory, or the like. Data and the like are stored, for example, in the volatile memory. A program, a table, a map and the like are stored, for example, in the nonvolatile memory. At least a portion of the storage unit 84 may be provided in the above-described processor, the integrated circuit, or the like.

The electrical current value determination unit 86 determines whether or not the electrical current value acquired using the electrical current sensor 70 provided in the storage device (the first electrical power storage device 64a to the fourth electrical power storage device 64d) is less than or equal to a determination threshold value used for determining whether or not charging or discharging is occurring.

The control unit 88 controls the operation of the electrical power supply system 30. For example, in the case that the electrical current value determination unit 86 determines that the electrical current value acquired by the electrical current sensor 70 is less than or equal to the determination threshold value, the control unit 88 carries out a control in order to increase the electrical current value to be greater than the determination threshold value.

In the case that, despite the control being carried out by the control unit 88 in order to make the electrical current value greater than the determination threshold value, the electrical current value acquired using the electrical current sensor 70 is less than or equal to the determination threshold value, the disconnection determination unit 90 determines that a disconnection has occurred in the wiring connected to the electrical power storage device (the first electrical power storage device 64a to the fourth electrical power storage device 64d) that is the target of the inspection.

### 3. Operation of Electrical Power Supply System

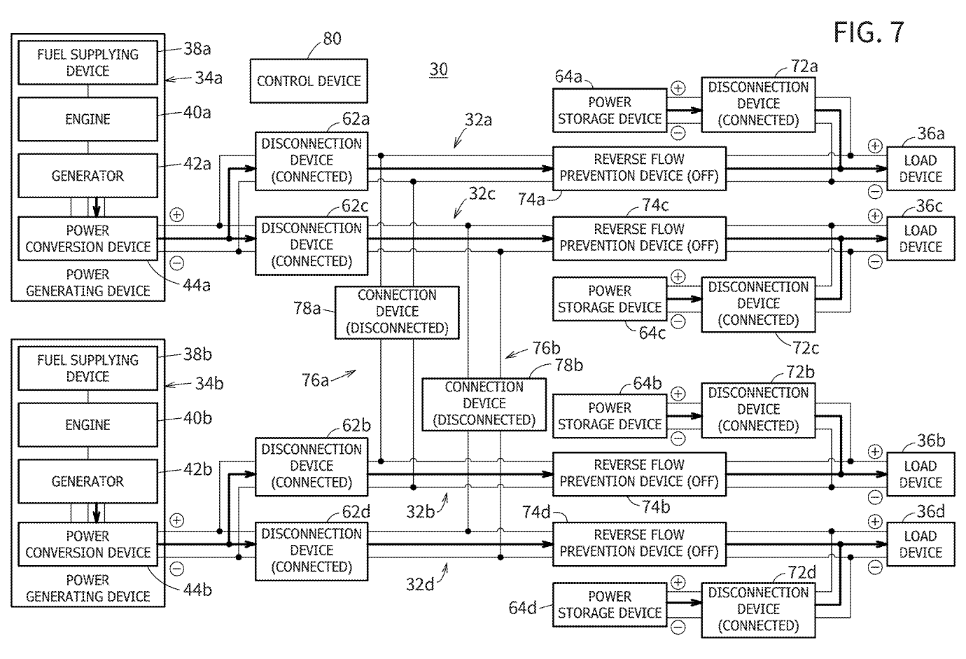

FIG. 7 is a diagram showing the operation of the electrical power supply system 30 in the one embodiment. FIG. 7 shows a normal operation of the electrical power supply system 30 at a time when the moving object 10 is in flight. The arrows shown in FIG. 7 indicate electrical power supply pathways. Moreover, the configuration of the electrical power supply circuit to the first load device 36a and the third load device 36c is the same as the configuration of the electrical power supply circuit to the second load device 36b and the fourth load device 36d. Therefore, in this instance, a description concerning the operation of supplying the electrical power to the first load device 36a and the third load device 36c will be provided herein, and a description concerning the operation of supplying the electrical power to the second load device 36b and the fourth load device 36d will be omitted.

As shown in FIG. 7, the first electrical power generating device 34a is connected by the disconnection device 62a to the first electrical power supply circuit 32a, and the first electrical power generating device 34a is connected by the disconnection device 62c to the third electrical power supply circuit 32c. Consequently, the three-phase AC electrical power output from the first electrical power generator 42a is converted into a DC electrical power in the first electrical power conversion device 44a, and is supplied to the first load device 36a and the third load device 36c.

The first electrical power storage device 64a is connected by the disconnection device 72a to the first load device 36a. In accordance therewith, it becomes possible for discharging from the first electrical power storage device 64a, or alternatively, for charging to the first electrical power storage device 64a to be carried out. The third electrical power storage device 64c is connected by the disconnection device 72c to the third load device 36c. In accordance therewith, it becomes possible for discharging from the third electrical power storage device 64c, or alternatively, for charging to the third electrical power storage device 64c to be carried out.

### 4. Disconnection Inspection Process

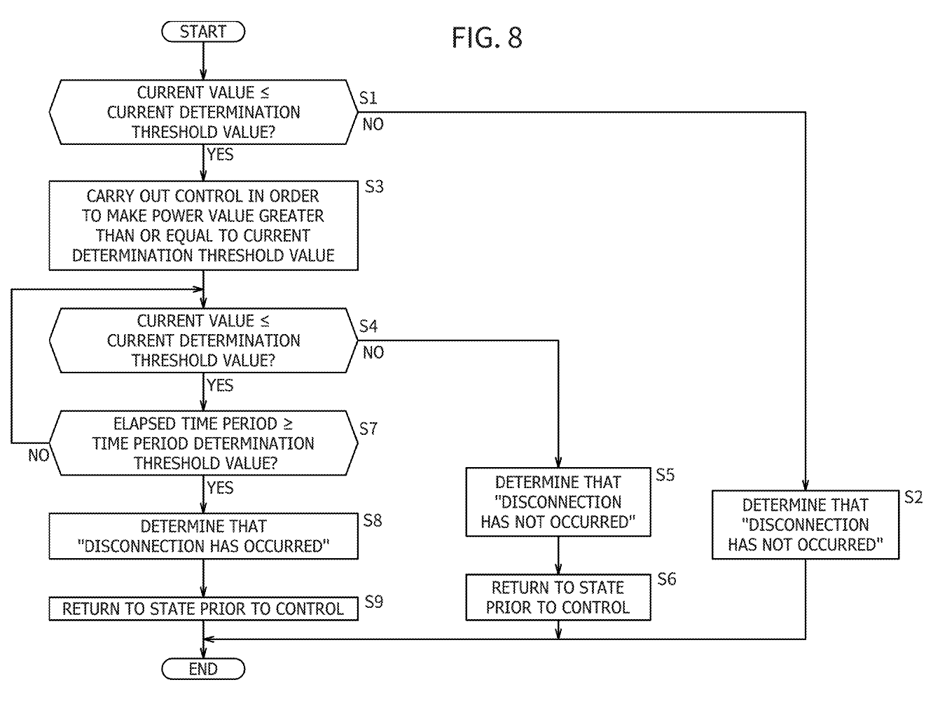

FIG. 8 is a flowchart of a disconnection inspection process. In this instance, a description will be given concerning a process for inspecting whether or not a disconnection has occurred in the wiring connecting the first electrical power storage device 64a and the first electrical power supply circuit 32a. In the following description, the wiring that is the target of the disconnection inspection is referred to as an inspection target wiring. Moreover, in the following description, the term "electrical current sensor 70" refers to the electrical current sensor 70 that is provided in the first electrical power storage device 64a.

The disconnection inspection process is carried out by the computation unit 82 during a period in which the electrical power consumption of the moving object 10 is low. At a time during vertical takeoff and landing of the moving object 10 and at a time when the moving object 10 is ascending, since the plurality of VTOL rotors 12 are used, the electrical power consumption of the moving object 10 is large. On the other hand, at a time during cruising of the moving object 10 and at a time when the moving object 10 is descending, since the plurality of VTOL rotors 12 (the electric motors 16) are not substantially used, the electrical power consumption of the moving object 10 is comparatively small. The computation unit 82 carries out the disconnection inspection process at the time of cruising or at a time of descending when the electrical power consumption of the moving object 10 is low. The computation unit 82 may carry out the disconnection inspection process periodically at the time when the moving object 10 is cruising or at the time when the moving object 10 is descending, or may carry out the disconnection inspection process at any arbitrary timing.

An outline of the disconnection inspection process is as follows. In the case that a disconnection occurs in the wiring which is the target of the disconnection inspection that is connected to the first electrical power storage device 64a, the electrical current value acquired by the electrical current sensor 70 becomes less than or equal to a determination threshold value for determining whether or not charging or discharging is occurring (usually zero). In contrast thereto, even in the case that the electrical power supplied from the first electrical power generating device 34a to the first electrical power supply circuit 32a and the electrical power consumed by the first load device 36a are balanced, the electrical current value acquired by the electrical current sensor 70 becomes less than or equal to the determination threshold value. Therefore, in the case that the electrical current value acquired by the electrical current sensor 70 is less than or equal to the determination threshold value, it is not possible to distinguish between whether the inspection target wiring that is connected to the first electrical power storage device 64a is disconnected, or whether the first electrical power generating device 34a is simply not charging or discharging.

In the disconnection inspection process, in the case that the electrical current value acquired by the electrical current sensor 70 is less than or equal to the determination threshold value, the computation unit 82 carries out a control to prompt the charging or the discharging of the first electrical power storage device 64a. Thereafter, the computation unit 82, by once again determining whether or not the electrical current value acquired by the electrical current sensor 70 is less than or equal to the determination threshold value, determines whether or not a disconnection has occurred in the inspection target wiring. The disconnection inspection process will be specifically described below with reference to FIG. 8.

In step S1, the electrical current value determination unit 86 determines whether or not the electrical current value acquired by the electrical current sensor 70 is less than or equal to the determination threshold value used for determining whether or not charging or discharging is occurring. The determination threshold value, for example, is zero. The determination threshold value is stored in advance in the storage unit 84. In the case that the electrical current value acquired by the electrical current sensor 70 is less than or equal to the determination threshold value (step S1: YES), the process transitions to step S3. On the other hand, in the case that the electrical current value acquired by the electrical current sensor 70 is greater than the determination threshold value (step S1: NO), the process transitions to step S2.

Incidentally, at a time during charging and at a time during discharging of the first electrical power storage device 64a, the directions of the electrical current flowing through the inspection target wiring are opposite. In step S1, the electrical current value determination unit 86 ignores the direction of the current. For example, the electrical current value determination unit 86 compares the absolute value of the electrical current value acquired by the electrical current sensor 70 with the determination threshold value.

When the process transitions from step S1 to step S2, the disconnection determination unit 90 determines that "a disconnection has not occurred." When step S2 is completed, the disconnection inspection of the inspection target wiring that is connected to the first electrical power storage device 64a comes to an end. The disconnection determination unit 90 may display the result of the disconnection inspection on a non-illustrated display device.

When the process transitions from step S1 to step S3, the control unit 88 carries out a control in order to make the electrical current value acquired by the electrical current sensor 70 greater than the determination threshold value. In step S3, the control unit 88 carries out a control to prompt the charging and discharging of the first electrical power storage device 64a. Stated otherwise, the control unit 88 carries out a control to cause the electrical power that is charged to the first electrical power storage device 64a or the electrical power that is discharged from the first electrical power storage device 64a to change. Namely, the control unit 88 carries out a control to cause the state of charging and discharging of the first electrical power storage device 64a to change.

For example, by changing the electrical power output from the first electrical power generating device 34a, the control unit 88 can carry out a control in order to make the electrical current value acquired by the electrical current sensor 70 greater than the determination threshold value. This control is referred to as an electrical power generating control. In the electrical power generating control, the control unit 88 controls the switching elements 54 of the first electrical power conversion device 44a. Moreover, the control unit 88, when carrying out the electrical power generating control, may control an injector of the first fuel supplying device 38a.

For example, the control unit 88, by changing the distribution of the electrical power supplied to the first winding 58a of the electric motor 20-1 and the electrical power supplied to the second winding 58b of the electric motor 20-1, can carry out a control in order to make the electrical current value acquired by the electrical current sensor 70 greater than the determination threshold value. This control is referred to as an electrical power distribution control. In the electrical power distribution control, the control unit 88 controls the switching element of the inverter 60a of the first load device 36a and the switching element of the inverter 60b of the second load device 36b. The control unit 88, when carrying out the electrical power distribution control, makes the sum of the electrical power supplied to the first winding 58a and the electrical power supplied to the second winding 58b equal to the sum prior to the control.

Hereinafter, a description will be given of examples of the control (examples of a first control and a second control) carried out by the control unit 88 in step S3. The first control is a control in which the electrical power generating control and the electrical power distribution control are carried out. The second control is a control in which only the electrical power distribution control is carried out.

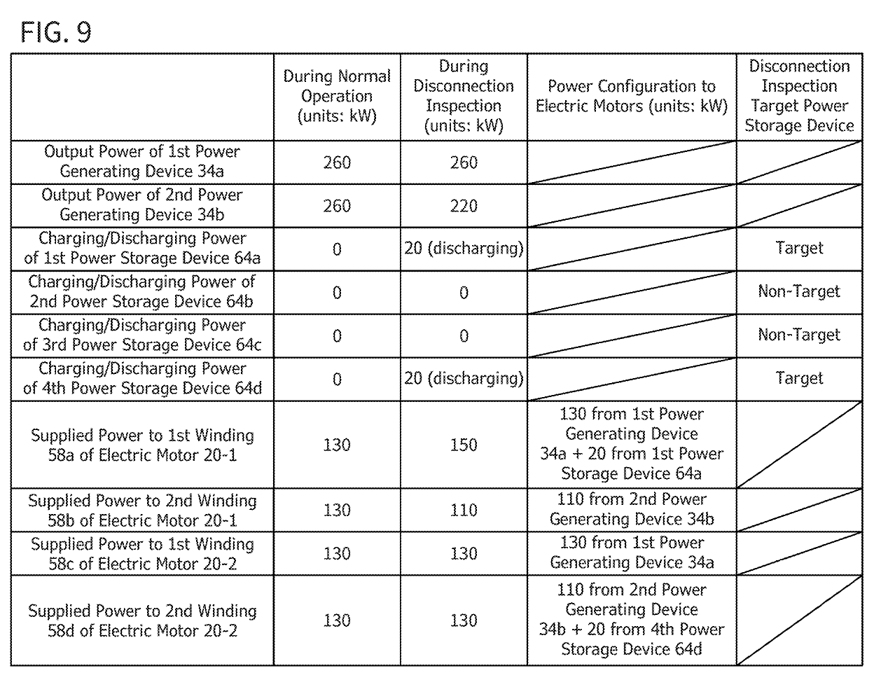

FIG. 9 is a table showing the input and output electrical power in the electrical power supply system 30 at a time of normal operation, and the input and output electrical power in the electrical power supply system 30 at a time during the disconnection inspection (at a time of the first control). FIG. 9 shows the output power of each of the electrical power generating devices, the charging and discharging electrical power of each of the electrical power storage devices, and the electrical power supplied to each of the windings. The numerical values shown in FIG. 9 are used in order to describe the control of step S3. As noted previously, at a time during cruising of the moving object 10 and at a time when the moving object 10 is descending, the electric motors 16 are not substantially used. Therefore, the electrical power supplied to the electric motors 16 can be considered to be zero. Meanwhile, during the flight of the moving object 10, other electrically powered machines are also used. In this instance, to facilitate the description, the electrical power supplied to the other electrically powered machines apart from the two electric motors 20 will be ignored.

Under normal circumstances, the control unit 88 controls the first electrical power generating device 34a, the second electrical power generating device 34b, and the respective inverters that are connected to each of the windings of the two electric motors 20, in a manner so that the sum of the output electrical power of the first electrical power generating device 34a and the output electrical power of the second electrical power generating device 34b becomes balanced with the sum of the electrical power supplied to each of the windings of the two electric motors 20.

At a time of the disconnection inspection (at a time of the first control), the control unit 88 controls the first electrical power generating device 34a, the second electrical power generating device 34b, and the inverters that are connected to each of the windings of the two electric motors 20, in a manner so that the first electrical power storage device 64a undergoes charging and discharging. For example, as shown in FIG. 9, the control unit 88 controls the first electrical power generating device 34a and the inverters that are connected to each of the windings of the electric motor 20-2, in a manner so that the output electrical power of the first electrical power generating device 34a becomes equal to that at the time of normal operation, and the distribution of the electrical power supplied to each of the windings of the electric motor 20-2 becomes equal to that at the time of normal operation. Further, as shown in FIG. 9, the control unit 88 controls the second electrical power generating device 34b and the inverters that are connected to each of the windings of the electric motor 20-1, in a manner so that the output electrical power of the second electrical power generating device 34b is reduced more so than at the time of normal operation, and the distribution of the electrical power supplied to each of the windings of the electric motor 20-1 becomes changed compared to that at the time of normal operation.

According to the first control, the charging and discharging electrical power of the first electrical power storage device 64a changes before and after the first control. Specifically, the first electrical power storage device 64a carries out discharging. Therefore, by carrying out the first control, the control unit 88 is capable of carrying out the disconnection inspection of the inspection target wiring that is connected to the first electrical power storage device 64a. Moreover, as shown in FIG. 9, according to the first control, the charging and discharging electrical power of the fourth electrical power storage device 64d also changes before and after the first control. Specifically, the fourth electrical power storage device 64d carries out discharging. Therefore, by carrying out the first control, the control unit 88, together with being capable of carrying out the disconnection inspection of the inspection target wiring that is connected to the first electrical power storage device 64a, is capable of carrying out the disconnection inspection of the inspection target wiring that is connected to the fourth electrical power storage device 64d.

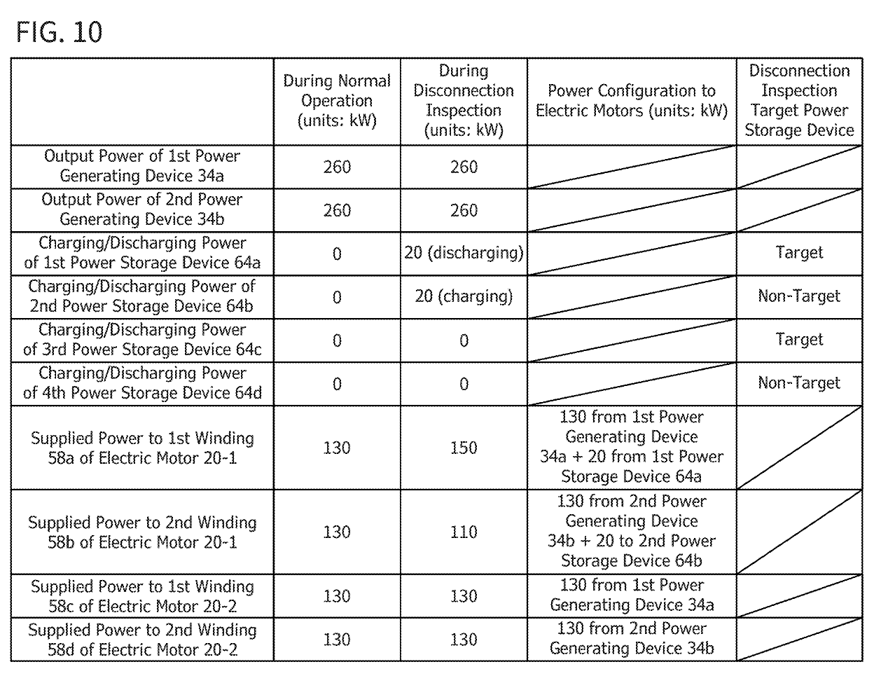

FIG. 10 is a table showing the input and output electrical power in the electrical power supply system 30 at a time of normal operation, and the input and output electrical power in the electrical power supply system 30 at a time during the disconnection inspection (at a time of the second control). FIG. 10 shows the output power of each of the electrical power generating devices, the charging and discharging electrical power of each of the electrical power storage devices, and the electrical power supplied to each of the windings. The numerical values shown in FIG. 10 are used in order to describe the control of step S3. Similar to the description of the first control, in this instance, to facilitate the description, the electrical power supplied to the other electrically powered machines apart from the two electric motors 20 will be ignored.

At a time of the disconnection inspection (at a time of the second control), the control unit 88 controls the first electrical power generating device 34a, the second electrical power generating device 34b, and the inverters that are connected to each of the windings of the two electric motors 20, in a manner so that the first electrical power storage device 64a undergoes charging and discharging. For example, as shown in FIG. 10, the control unit 88 controls the first electrical power generating device 34a and the second electrical power generating device 34b, in a manner so that the output electrical power of the first electrical power generating device 34a and the output electrical power of the second electrical power generating device 34b become equal to that at the time of normal operation. Further, as shown in FIG. 10, the control unit 88 also controls the inverters that are connected to each of the windings of the electric motor 20-2, in a manner so that the distribution of the electrical power supplied to each of the windings of the electric motor 20-2 is equal to that at the time of normal operation. Further, as shown in FIG. 10, the control unit 88 also controls the inverters that are connected to each of the windings of the electric motor 20-1, in a manner so that the distribution of the electrical power supplied to each of the windings of the electric motor 20-1 is changed compared to that at the time of normal operation.

According to the second control, the charging and discharging electrical power of the first electrical power storage device 64a changes before and after the second control. Specifically, the first electrical power storage device 64a carries out discharging. Therefore, by carrying out the second control, the control unit 88 is capable of carrying out the disconnection inspection of the inspection target wiring that is connected to the first electrical power storage device 64a. Moreover, as shown in FIG. 10, according to the second control, the charging and discharging electrical power of the second electrical power storage device 64b also changes before and after the second control. Specifically, the second electrical power storage device 64b carries out charging. Therefore, by carrying out the second control, the control unit 88, together with being capable of carrying out the disconnection inspection of the inspection target wiring that is connected to the first electrical power storage device 64a, is capable of carrying out the disconnection inspection of the inspection target wiring that is connected to the second electrical power storage device 64b.

In this instance, although a description has been given with reference to FIGS. 9 and FIG. 10 concerning the first control and the second control, other patterns for changing the input and output electrical power of each of the devices may also be considered. The control unit 88, in such other patterns for changing, is also capable of changing the input and output electrical power of each of the devices.

When the control in step S3 is completed, the control unit 88, by using a non-illustrated timer, starts counting the elapsed time period after the control is completed.

In step S4, the electrical current value determination unit 86 again carries out the same determination as in step S1. More specifically, the electrical current value determination unit 86 determines whether or not the electrical current value acquired by the electrical current sensor 70 is less than or equal to the determination threshold value used for determining whether or not charging or discharging is occurring. In the case that the electrical current value acquired by the electrical current sensor 70 is less than or equal to the determination threshold value (step S4: YES), the process transitions to step S7. On the other hand, in the case that the electrical current value acquired by the electrical current sensor 70 is greater than the determination threshold value (step S4: NO), the process transitions to step S5.

When the process transitions from step S4 to step S5, the disconnection determination unit 90 determines that "a disconnection has not occurred." The disconnection determination unit 90 may display the result of the disconnection inspection on a non-illustrated display device. After the process of step S5, the process transitions to step S6.

In step S6, the control unit 88 returns the power input/output state to the state prior to the control of step S3. For example, the control unit 88, in the case of having carried out the electrical power generating control in step S3, returns the electrical power generating state of the first electrical power generating device 34a to the electrical power generating state prior to the control. In the case that the control unit 88 has carried out the electrical power distribution control in step S3, the process returns the electrical power distribution state to the first winding 58a and the second winding 58b to the electrical power distribution state prior to the control. When step S6 is completed, the disconnection inspection of the inspection target wiring that is connected to the first electrical power storage device 64a comes to an end.

When the process transitions from step S4 to step S7, the disconnection determination unit 90 determines whether or not the elapsed time period counted by the timer is less than or equal to a time period determination threshold value. The time period determination threshold value is stored in advance in the storage unit 84. In the case that the elapsed time period is greater than or equal to the time period determination threshold value (step S7: YES), the process transitions to step S8. On the other hand, in the case that the elapsed time period is less than the time period determination threshold value (step S7: NO), the process returns to step S4.

When the process transitions from step S7 to step S8, the disconnection determination unit 90 determines that "a disconnection has occurred." Provisionally, in the case that a disconnection has not occurred in the inspection target wiring, the electrical current value acquired by the electrical current sensor 70 should undergo a change prior to and after step S3. On the other hand, in the case that a disconnection has occurred in the inspection target wiring, the electrical current value acquired by the electrical current sensor 70 does not undergo a change prior to and after step S3. At the point in time of step S8, the fact that the electrical current value remains less than or equal to the electrical current determination threshold value (for example, zero) can be considered as indicating that a disconnection has occurred in the inspection target wiring. The disconnection determination unit 90 may display the result of the disconnection inspection on a non-illustrated display device. After the process of step S8, the process transitions to step S9.

In step S9, in the same manner as in step S6, the control unit 88 returns the power input/output state to the state prior to the control of step S3. When step S9 is completed, the disconnection inspection process of the inspection target wiring that is connected to the first electrical power storage device 64a comes to an end.

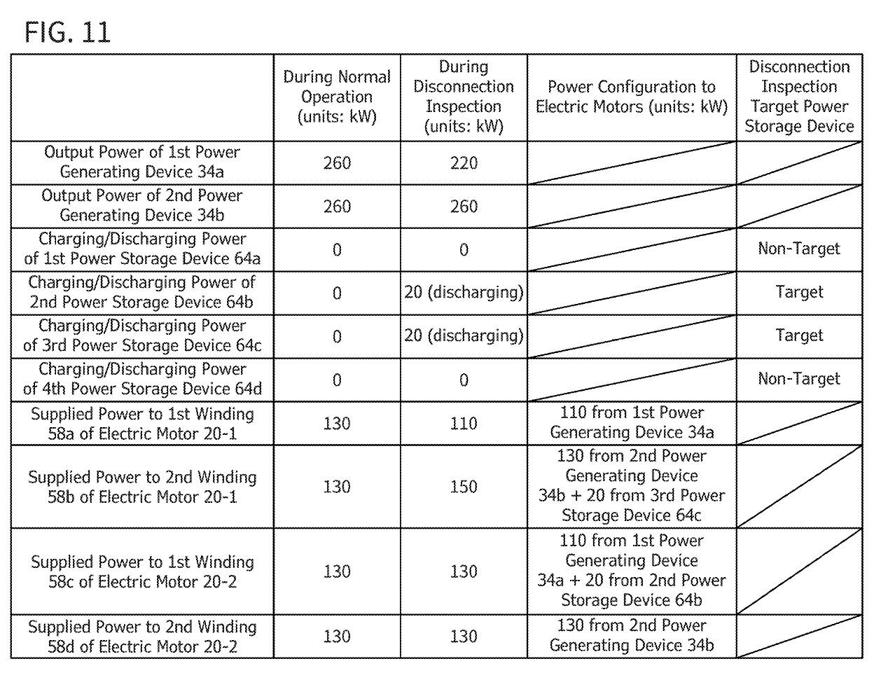

When the disconnection inspection process of the inspection target wiring that is connected to the first electrical power storage device 64a comes to an end, the disconnection inspection process of the inspection target wiring that is connected to another electrical power storage device is started. In the case that the first control is carried out in step S3, in addition to the inspection of the inspection target wiring that is connected to the first electrical power storage device 64a, the inspection of the inspection target wiring that is connected to the fourth electrical power storage device 64d is also carried out. Therefore, next, as shown in FIG. 11, the disconnection inspection of the inspection target wiring that is connected to the second electrical power storage device 64b, and the disconnection inspection of the inspection target wiring that is connected to the third electrical power storage device 64c are carried out.

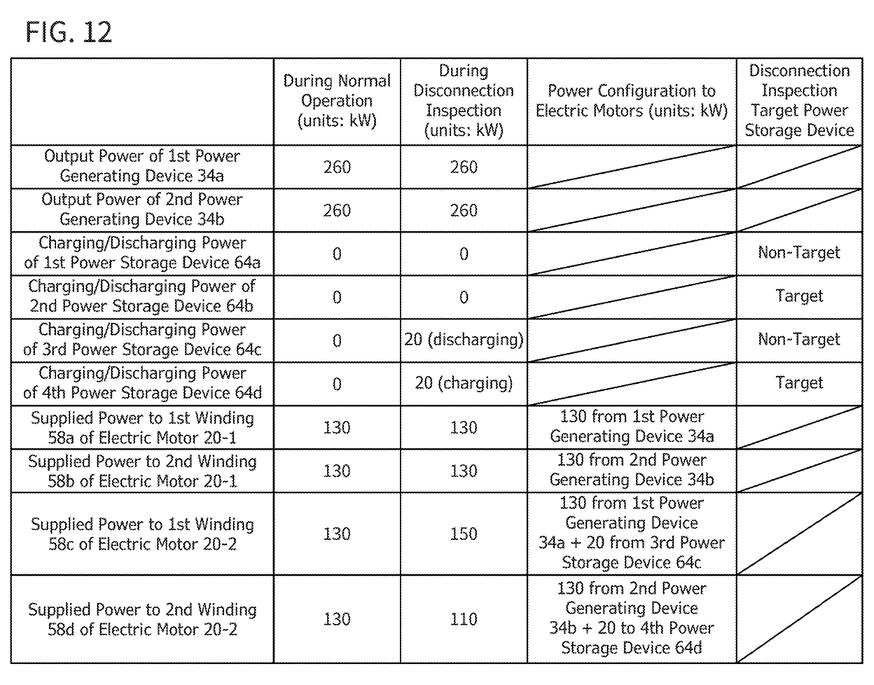

On the other hand, in the case that the second control is carried out in step S3, in addition to the inspection of the inspection target wiring that is connected to the first electrical power storage device 64a, the inspection of the inspection target wiring that is connected to the third electrical power storage device 64c is also carried out. Therefore, next, as shown in FIG. 12, the disconnection inspection of the inspection target wiring that is connected to the second electrical power storage device 64b, and the disconnection inspection of the inspection target wiring that is connected to the fourth electrical power storage device 64d are carried out.

Moreover, in the case that the disconnection determination unit 90 determines that "a disconnection has occurred," the disconnection inspection comes to an end. At this time, it is preferable that the control device 80 transitions to an abnormality control. As an example thereof, the control unit 88 may switch the first connection device 78a from a disconnected state to a connected state. In accordance therewith, it becomes possible for the electrical power that cannot be supplied from the first electrical power storage device 64a to the first load device 36a to be supplemented by the second electrical power generating device 34b.

According to the above-described embodiment, it is possible to carry out the disconnection inspection of the inspection target wiring based on the electrical current value acquired using the electrical current sensor 70.

According to the above-described embodiment, it is possible to carry out the disconnection inspection without causing the behavior of the moving object 10 to change. For example, in the above-described electrical power distribution control, although the distribution of the electrical power supplied to the two windings of the electric motor 20 is changed, since the total electrical power supplied to the two windings is not changed, the operation of the electric motor 20 does not undergo a change prior to and after the start of the disconnection inspection. As a result, the behavior of the moving object 10 does not change.

### 5. Supplementary Notes

In relation to the above-described disclosure, the following supplementary notes are further disclosed.

### Supplementary Note 1

The control device (80) of the present disclosure is the control device which is provided in the electrical power supply system (30) that is capable of supplying electrical power from the electrical power generating device (34a, 34b) and the electrical power storage device (64a to 64d) to the load device (36a to 36d), and further, that is capable of supplying electrical power from the electrical power generating device to the electrical power storage device, the control device comprising the electrical current value determination unit (86) that determines whether or not the electrical current value acquired using the electrical current sensor (70) that detects the charging or discharging electrical current of the electrical power storage device is less than or equal to the determination threshold value used for determining whether or not charging or discharging is occurring, the control unit (88) which, in the case that it is determined by the electrical current value determination unit that the electrical current value acquired by the electrical current sensor is less than or equal to the determination threshold value, carries out the control in order to make the electrical current value greater than the determination threshold value, and the disconnection determination unit (90) which, in the case that, despite the control being carried out by the control unit in order to make the electrical current value greater than the determination threshold value, the electrical current value acquired using the electrical current sensor is less than or equal to the determination threshold value, determines that a disconnection has occurred in the wiring connected to the electrical power storage device.

In accordance with the above-described configuration, it is possible to carry out the disconnection inspection of the inspection target wiring based on the electrical current value acquired using the electrical current sensor.

### Supplementary Note 2

In the control device according to Supplementary Note 1, the control device, by changing the electrical power output from the electrical power generating device, may carry out the control in order to make the electrical current value greater than the determination threshold value.

Supplementary Note 3

The control device provided in the electrical power supply system that is capable of supplying the electrical power from the first electrical power generating device and the first electrical power storage device to the first winding (58a, 58c) of the double-winding motor (20), that is capable of supplying the electrical power from the first electrical power generating device to the first electrical power storage device, that is capable of supplying the electrical power from the second electrical power generating device to the second winding (58b, 58d) of the double-winding motor, and further, that is capable of supplying the electrical power from the second electrical power generating device to the second electrical power storage device, the control device comprising the electrical current value determination unit that determines whether or not the electrical current value acquired using the electrical current sensor that detects the charging or discharging electrical current of the first electrical power storage device is less than or equal to the determination threshold value used for determining whether or not charging or discharging is occurring, the control unit which, in the case that it is determined by the electrical current value determination unit that the electrical current value acquired by the electrical current sensor is less than or equal to the determination threshold value, carries out a control in order to make the electrical current value greater than the determination threshold value, and the disconnection determination unit which, in the case that, despite the control being carried out by the control unit in order to make the electrical current value greater than the determination threshold value, the electrical current value acquired using the electrical current sensor is less than or equal to the determination threshold value, determines that a disconnection has occurred in the wiring connected to the first electrical power storage device.

In accordance with the above-described configuration, it is possible to carry out the disconnection inspection of the inspection target wiring based on the electrical current value acquired using the electrical current sensor.

### Supplementary Note 4

In the control device according to Supplementary Note 3, by the computer executable instruction being executed by the at least one processor, the control device, by changing the distribution of the electrical power supplied to the first winding and the electrical power supplied to the second winding, and while maintaining the sum of the electrical power supplied to the first winding and the electrical power supplied to the second winding, may carry out a control in order to make the electrical current value greater than the determination threshold value.

### Supplementary Note 5

In the control device according to Supplementary Note 3, the control device, by changing the electrical power output from the first electrical power generating device, may carry out the control in order to make the electrical current value greater than the determination threshold value.

### Supplementary Note 6

The electrical power supply system of the present disclosure is equipped with the control device according to any one of Supplementary Notes 1 to 5.

### Supplementary Note 7

The control method of the present disclosure is the control method for the electrical power supply system which is capable of supplying the electrical power from the electrical power generating device and the electrical power storage device to the load device, and further, which is capable of supplying the electrical power from the electrical power generating device to the electrical power storage device, the control method comprising the electrical current value determination step of determining whether or not the electrical current value acquired using the electrical current sensor that detects the charging or discharging electrical current of the electrical power storage device is less than or equal to the determination threshold value used for determining whether or not charging or discharging is occurring, the control step in which, in the case that it is determined in the electrical current value determination step that the electrical current value acquired by the electrical current sensor is less than or equal to the determination threshold value, carries out the control in order to make the electrical current value greater than the determination threshold value, and the disconnection determination step of determining, in the case that, despite the control being carried out in the control step in order to make the electrical current value greater than the determination threshold value, the electrical current value acquired using the electrical current sensor is less than or equal to the determination threshold value, that a disconnection has occurred in the wiring connected to the electrical power storage device.

### Supplementary Note 8

The control method of the present disclosure is the control method for the electrical power supply system which is capable of supplying the electrical power from the first electrical power generating device and the first electrical power storage device to the first winding of the double-winding motor, and which is capable of supplying the electrical power from the first electrical power generating device to the first electrical power storage device, and further, which is capable of supplying the electrical power from the second electrical power generating device and the second electrical power storage device to the second winding of the double-winding motor, and which is capable of supplying the electrical power from the second electrical power generating device to the second electrical power storage device, the control method comprising the electrical current value determination step of determining whether or not the electrical current value acquired using the electrical current sensor that detects the charging or discharging electrical current of the first electrical power storage device is less than or equal to the determination threshold value used for determining whether or not charging or discharging is occurring, the control step which, in the case that it is determined in the electrical current value determination step that the electrical current value acquired by the electrical current sensor is less than or equal to the determination threshold value, carries out a control in order to make the electrical current value greater than the determination threshold value, and the disconnection determination step of determining, in the case that, despite the control being carried out in the control step in order to make the electrical current value greater than the determination threshold value, the electrical current value acquired using the electrical current sensor is less than or equal to the determination threshold value, that a disconnection has occurred in the wiring connected to the first electrical power storage device.

Although concerning the present disclosure, a detailed description thereof has been presented above, the present disclosure is not necessarily limited to the individual embodiments described above. These embodiments may be subjected to various additions, substitutions, modifications, partial deletions and the like, within a range that does not deviate from the essence and gist of the present disclosure, or the spirit of the present disclosure as derived from the content described in the claims and equivalents thereof. Further, the embodiments can also be implemented together in combination. For example, in the above-described embodiments, the order of each of the operations and the order of each of the processes are illustrated as examples, and the present invention is not necessarily limited to these features. The same also applies to cases in which numerical values or mathematical expressions are used in the description of the aforementioned embodiments.

1. A control device provided in an electrical power supply system configured to be capable of supplying electrical power from an electrical power generating device and an electrical power storage device to a load device, and further, to be capable of supplying electrical power from the electrical power generating device to the electrical power storage device, the control device comprising:
at least one processor configured to execute a computer executable instruction that is stored in a memory;
wherein, by the computer executable instruction being executed by the at least one processor, the control device:
determines whether or not an electrical current value acquired using an electrical current sensor configured to detect a charging or discharging electrical current of the electrical power storage device is less than or equal to a determination threshold value used for determining whether or not charging or discharging is occurring;
in a case that it is determined that the electrical current value acquired by the electrical current sensor is less than or equal to the determination threshold value, carries out a control in order to make the electrical current value greater than the determination threshold value; and
in a case that, despite the control being carried out in order to make the electrical current value greater than the determination threshold value, the electrical current value acquired using the electrical current sensor is less than or equal to the determination threshold value, determines that a disconnection has occurred in a wiring connected to the electrical power storage device.

2. The control device according to claim 1, wherein, by the computer executable instruction being executed by the at least one processor, the control device, by changing the electrical power output from the electrical power generating device, carries out the control in order to make the electrical current value greater than the determination threshold value.

3. A control device provided in an electrical power supply system configured to be capable of supplying electrical power from a first electrical power generating device and a first electrical power storage device to a first winding of a double-winding motor, and to be capable of supplying electrical power from the first electrical power generating device to the first electrical power storage device, and further, to be capable of supplying electrical power from a second electrical power generating device and a second electrical power storage device to a second winding of the double-winding motor, and to be capable of supplying electrical power from the second electrical power generating device to the second electrical power storage device, the control device comprising:
at least one processor configured to execute a computer executable instruction that is stored in a memory;
wherein, by the computer executable instruction being executed by the at least one processor, the control device:
determines whether or not an electrical current value acquired using an electrical current sensor configured to detect a charging or discharging electrical current of the first electrical power storage device is less than or equal to a determination threshold value used for determining whether or not charging or discharging is occurring;
in a case that it is determined that the electrical current value acquired by the electrical current sensor is less than or equal to the determination threshold value, carries out a control in order to make the electrical current value greater than the determination threshold value; and
in a case that, despite the control being carried out in order to make the electrical current value greater than the determination threshold value, the electrical current value acquired using the electrical current sensor is less than or equal to the determination threshold value, determines that a disconnection has occurred in a wiring connected to the first electrical power storage device.

4. The control device according to claim 3, wherein, by the computer executable instruction being executed by the at least one processor, the control device, by changing the distribution of the electrical power supplied to the first winding and the electrical power supplied to the second winding, while maintaining a sum of the electrical power supplied to the first winding and the electrical power supplied to the second winding, carries out the control in order to make the electrical current value greater than the determination threshold value.

5. The control device according to claim 3, wherein, by the computer executable instruction being executed by the at least one processor, the control device, by changing the electrical power output from the first electrical power generating device, carries out the control in order to make the electrical current value greater than the determination threshold value.

6. An electrical power supply system comprising the control device according to claim 1.

7. A control method in which at least one processor executes a control of an electrical power supply system configured to be capable of supplying electrical power from an electrical power generating device and an electrical power storage device to a load device, and further, to be capable of supplying electrical power from the electrical power generating device to the electrical power storage device, the control method comprising:
determining whether or not an electrical current value acquired using an electrical current sensor configured to detect a charging or discharging electrical current of the electrical power storage device is less than or equal to a determination threshold value used for determining whether or not charging or discharging is occurring;
carrying out, in a case that it is determined that the electrical current value acquired by the electrical current sensor is less than or equal to the determination threshold value, a control in order to make the electrical current value greater than the determination threshold value; and
determining, in a case that, despite the control being carried out in order to make the electrical current value greater than the determination threshold value, the electrical current value acquired using the electrical current sensor is less than or equal to the determination threshold value, that a disconnection has occurred in a wiring connected to the electrical power storage device.

8. A control method in which at least one processor executes a control of an electrical power supply system configured to be capable of supplying electrical power from a first electrical power generating device and a first electrical power storage device to a first winding of a double-winding motor, and to be capable of supplying electrical power from the first electrical power generating device to the first electrical power storage device, and further, to be capable of supplying electrical power from a second electrical power generating device and a second electrical power storage device to a second winding of the double-winding motor, and to be capable of supplying electrical power from the second electrical power generating device to the second electrical power storage device, the control method comprising:
determining whether or not an electrical current value acquired using an electrical current sensor configured to detect a charging or discharging electrical current of the first electrical power storage device is less than or equal to a determination threshold value used for determining whether or not charging or discharging is occurring;
carrying out, in a case that it is determined that the electrical current value acquired by the electrical current sensor is less than or equal to the determination threshold value, a control in order to make the electrical current value greater than the determination threshold value; and
determining, in a case that, despite the control being carried out in order to make the electrical current value greater than the determination threshold value, the electrical current value acquired using the electrical current sensor is less than or equal to the determination threshold value, that a disconnection has occurred in a wiring connected to the first electrical power storage device.
